(19) United States
(12) Patent Application Publication
(10) Pub. No.: US 2026/0123552 A1
(43) Pub. Date: Apr. 30, 2026

(54) INTEGRATED CIRCUIT PACKAGE HAVING A SPLIT LEADFRAME

(71) Applicant: TEXAS INSTRUMENTS INCORPORATED, DALLAS, TX (US)

(72) Inventors: Hsuan-Lien CHOU, NEW TAIPEI CITY (TW); Bob LEE, ZHONGHE DIST. (TW); Chia Wei CHANG, TAOYUAN CITY (TW)

(21) Appl. No.: 18/933,427

(22) Filed: Oct. 31, 2024

(51) Int. Cl. H01L 23/498; H01L 21/48; H01L 23/31; H01L 23/538; H01L 25/065

(52) U.S. Cl. CPC H10W 90/701; H10W 70/093; H10W 70/611; H10W 70/635; H10W 74/111; H10W 90/00

(57) ABSTRACT

An electronic device includes a leadframe having connection pads, where the connection pads are off-set in a direction elevated from the leadframe. A substrate is attached to the leadframe and at least one die is attached to the substrate. A mold compound encapsulates the substrate and the at least one die.

### TECHNICAL FIELD

The present disclosure relates to electronic devices, and more specifically to electronic devices having a split leadframe configuration.

### BACKGROUND

Electronic devices (e.g., integrated circuits) that include both a leadframe and a multi-metal layered substrate require processes to attach the substrate to the leadframe. The process includes applying a solder based material on pads of the leadframe and placing the substrate on the pads. One process includes depositing solder one-by-one on each pad of the leadframe and attaching the substrate to the pads. Another process includes a screen printing process, where the solder is deposited on all the pads of the leadframe in a single printing process.

### SUMMARY

In a described example, an electronic device includes a leadframe having connection pads, where the connection pads are off-set in a direction elevated from the leadframe. A substrate is attached to the leadframe and at least one die is attached to the substrate. A mold compound encapsulates the substrate and the at least one die.

In another described example, an electronic device includes a leadframe having internal leads, external leads, and connection pads, where the connection pads are off-set in a direction elevated from a top portion of the external leads. A substrate is attached to the leadframe and at least one die attached to the substrate. A mold compound encapsulates the substrate and the at least one die.

In still another described example, a method includes placing a leadframe on a platform such that external leads of the leadframe are placed on a first platform and connection pads of the leadframe are placed on a second platform, the second platform being elevated with respect to the first platform. A stencil is placed above the leadframe such that the stencil contacts outer, opposite ends of the connection pads. The stencil includes apertures aligned with the connection pads. A screen printing process is performed to deposit an interconnect in the apertures of the stencil and on the connection pads. A substrate is attached to the connection pads of the leadframe via the interconnect and at least one die is attached to the substrate. A mold compound is formed to encapsulate the substrate and the at least one die.

### BRIEF DESCRIPTION OF THE DRAWINGS

FIG. 1 is a cross-sectional view of an example electronic device.

FIG. 2 is a block diagram flow chart explaining a fabrication process of the electronic device of FIG. 1.

FIG. 3A is a cross-sectional view of a leadframe in the early stages of fabrication.

FIG. 3B is a cross-sectional view of the leadframe of FIG. 3A after placement on a screen printing platform.

FIG. 3C is a cross-sectional view of the leadframe of FIG. 3B after placement of a screen printing stencil on the leadframe.

FIG. 3D is a cross-sectional view of the leadframe of FIG. 3C undergoing a screen printing process.

FIG. 3E is a cross-sectional view of the leadframe of FIG. 3D after undergoing the screen printing process.

FIG. 3F is a cross-sectional view of the leadframe of FIG. 3E after removal of the screen printing stencil and removal of the leadframe from the screen printing platform.

FIG. 3G illustrates a cross-sectional view of the leadframe of FIG. 3F after attaching a substrate to the leadframe.

FIG. 3H illustrates a cross-sectional view of the leadframe and substrate of FIG. 3G after placement of one or more dies on a first metal layer of the substrate.

FIG. 3I illustrates a cross-sectional view of the leadframe and substrate of FIG. 3H after rotation of the leadframe and substrate 180°and after placement of one or more dies on a second metal layer of the substrate.

FIG. 3J illustrates a cross-sectional view of the leadframe and substrate of FIG. 3I after undergoing a formation of a mold compound.

FIG. 3K illustrates a cross-sectional view of the leadframe and substrate of FIG. 3J after rotation of the leadframe and substrate 180°

FIG. 3L illustrates a cross-sectional view of the substrate of FIG. 3K after forming and shaping external leads of the leadframe to form the electronic device of FIG. 1.

FIG. 4 is a block diagram flow chart explaining a fabrication process of the substrate illustrated in FIGS. 1 and 3L.

FIG. 5A illustrates a cross-sectional view of the substrate in the early stages of fabrication.

FIG. 5B illustrates a cross-sectional view of the substrate of FIG. 5A after undergoing a first laser drilling/etching process.

FIG. 5C illustrates a cross-sectional view of the substrate of FIG. 5B after undergoing a first photoresist material layer patterning.

FIG. 5D illustrates a cross-sectional view of the substrate of FIG. 5C after undergoing a first plating process.

FIG. 5E illustrates a cross-sectional view of the substrate of FIG. 5D after undergoing removal of the first photoresist material layer.

FIG. 5F illustrates a cross-sectional view of the substrate of FIG. 5E after rotation of the substrate by 180°.

FIG. 5G illustrates a cross-sectional view of the substrate of FIG. 5F after undergoing a second laser drilling/etching process.

FIG. 5H illustrates a cross-sectional view of the substrate of FIG. 5G after undergoing a second photoresist material layer patterning.

FIG. 5I illustrates a cross-sectional view of the substrate of FIG. 5H after undergoing a second plating process.

FIG. 5J illustrates a cross-sectional view of the substrate of FIG. 5I after undergoing removal of the second photoresist material layer.

FIG. 5K illustrates a cross-sectional view of the substrate of FIG. 5J after rotation of the substrate by 180°.

FIG. 6A is a cross-sectional view of another example leadframe.

FIGS. 6B and 6C are cross-sectional views of another example screen printing apparatus.

### DETAILED DESCRIPTION

Electronic device (e.g., integrated circuit (IC)) packages such as a quad-flat package (QFP) or a quad-flat no-lead package (QFN) that include both a leadframe and a multi-metal layered substrate require processes to attach the substrate to the leadframe. The process includes applying a solder based material on pads of the leadframe and placing the substrate on the pads. One process includes depositing solder one-by-one on each pad of the leadframe and attaching the substrate to the pads. This process, however, is time consuming and does not lend itself to high volume processing resulting in low throughput.

Another process includes a screen printing process, where the solder is deposited on all the pads of the leadframe in a single printing process. This process is suitable for high volume processing and therefore increases the throughput. In this process, a stencil is placed over the leadframe leaving openings over the pads of the leadframe where the solder is to be deposited. Once the screen printing process is completed, the stencil is removed from the leadframe. Upon removing the stencil, however, vibrations occur throughout the leadframe. The vibrations occur due to a configuration of the leadframe. Specifically, the leadframe has a down-set configuration where the pads are offset in a downward direction. In this configuration, the stencil is attached to the leadframe at several points on the leadframe making it more difficult to remove the stencil without causing vibrations in the leadframe. As a result, the vibrations cause the deposited solder to become displaced from the pads on the leadframe. In some instances, the solder may become so displaced that the solder falls over an edge of the pads and is thus completely displaced from the pads. These problems in turn cause performance and quality issues of the electronic device.

Disclosed herein is an electronic device and process of making that includes a split leadframe having an up-set connection pads that overcomes the aforementioned disadvantages. The up-set connection pads are raised with respect to leads of the leadframe, which facilitates the use of a solder screen printing process. More specifically, the up-set substrate connection pad configuration allows a screen printing stencil to be removed after the screen printing process without causing vibration to the leadframe. This is possible because the number of points that the stencil is attached to the leadframe is reduced. As a result, the solder screen printing process can be implemented to deposit solder on the substrate connection pads on the leadframe, which significantly increases throughput as opposed to depositing the solder on one connection pad at a time.

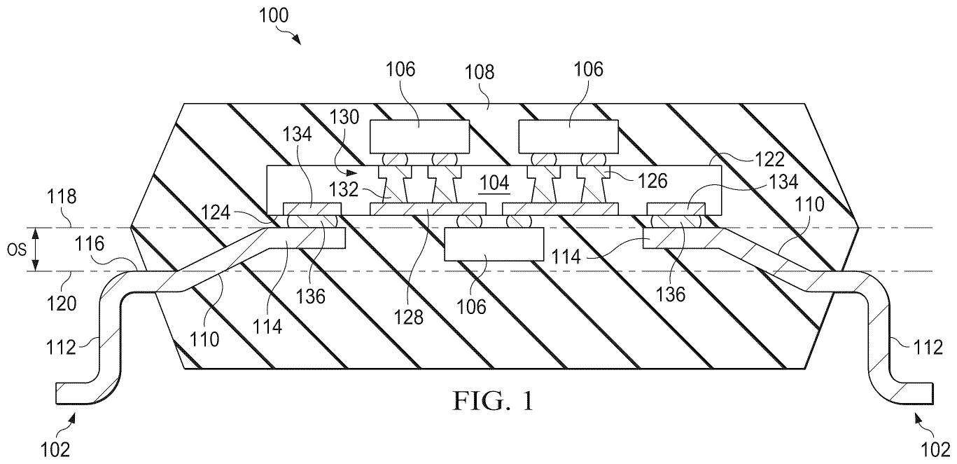

FIG. 1 is a cross-sectional view of an example electronic device (e.g., integrated circuit (IC)) 100. The example electronic device 100 described herein and illustrated in the figures is a leaded substrate type device such as but not limited to a quad-flat package (QFP), dual in-line package (DIP), a small outline package (SOP), etc. Thus, the example electronic device 100 illustrated in FIG. 1 is for illustrative purposes only and is not intended to limit the scope of the invention. The electronic device 100 includes a leadframe 102, a substrate 104 attached to the leadframe 102, one or more dies 106 attached to the substrate 104, and a mold compound 108.

The leadframe 102 is a split-type leadframe in that the leadframe 102 does not include a die attach pad. Rather, the leadframe includes connection pads in place of the die attach pad. Specifically, the leadframe 102 includes internal (inner) leads 110 disposed inside the mold compound 108 and external (outer) leads 112 disposed outside the mold compound 108. The external leads 112 extend from one end of the internal leads 110 away from the mold compound 108 and are configured to attach to an external electrical device (e.g., printed circuit board (PCB)). Instead of a die attach pad, the leadframe 102 includes multiple connection pads 114. Each connection pad 114 extends from an opposite end of the internal leads 110. The number of connection pads 114 can vary based on the type of package. For example, smaller packages may include 8-12 connection pads 114 (4-6 connection pads on each side of the leadframe). On the other hand, larger packages may include 14 or more connection pads 114 (7 or more connection pads on each side of the leadframe). The connection pads 114 are configured to attach to the substrate 104.

As illustrated in FIG. 1, the connection pads 114 are off-set in a direction elevated from the leadframe 102 represented by OS. Specifically, the connection pads 114 are up-set or elevated above a top portion 116 of the external leads 112. In other words, the connection pads 114 are on a first plane 118 and the top portion 116 of the external leads 112 are on a second plane 120, where the first plane 118 is elevated with respect to the second plane 120. The up-set configuration facilitates a solder screen printing process described further below.

The substrate (e.g., Epoxy, Ajinomoto Build-up Film (ABF), or Bismaleimide Triazine (BT)) 104 has a first surface 122 and a second surface 124 and includes multiple metal layers (traces) embedded in the substrate 104. The number of metal layers embedded in the substrate 104 can be any number ranging from 2 to N, where N is the maximum number for a given electronic device 100. For simplicity, the example electronic device 100 described herein and illustrated in FIG. 1 includes two metal layers comprising a first metal layer 126 embedded in the first surface 122 of the substrate 104 and a second metal layer 128 embedded in the second surface 124 of the substrate 104. The first metal layer 126 has an exposed surface that is substantially flush with the first surface 122 of the substrate 104. Similarly, the second metal layer 128 has an exposed surface that is substantially flush with the second surface 124 of the substrate 104.

A via layer 130 comprised of multiple vias 132 is disposed between the first metal layer 126 and the second metal layer 128. In other example electronic device packages, however, another via layer 130 may be disposed between the second metal layer 128 and a third metal layer, and still another via layer 130 may be disposed between the third metal layer and a fourth metal layer, etc. The via layer 130 provides an electrical connection between the first metal layer 126 and the second metal layer 128. Depending on the application and the package design, the vias 132 may be cylindrical, hollow vias with plated copper walls or solid copper vias or a combination to the two. The vias 132 facilitate the electrical connection between the first metal layer 126 and the second metal layer 128 and assist in the thermal performance of the electronic device 100.

The substrate 104 further includes contact pads 134 embedded in the second surface 124 of the substrate 104. The contact pads 134 have an exposed surface that is substantially flush with the second surface 124 of the substrate 104. The connection pads 114 of the leadframe 102 attach to the exposed surface of the contact pads 134 via first adhesive interconnects (e.g., solder) 136. Although not illustrated, the contact pads 134 can be electrically connected to any one of the first or second metal layers 126, 128 in the substrate 104 thereby providing an electrical connection from the one or more dies 106 to the external device.

An active side of the one or more dies (e.g., flip chip die) 106 attaches to the exposed surface of either the first metal layer 126 or the second metal layer 128 via second interconnects (e.g., solder balls) 136. The number of dies 106 can vary based on the application of the electronic device 100. For example, there may be one or more first dies 106 attached to the first metal layer 126 and one or more second dies 106 attached to the second metal layer 128. For simplicity, the example electronic device 100 illustrated in FIG. 1 includes a pair of (first and second) dies 106 attached to the first metal layer 126 and one (third) die 106 attached to the second metal layer 128. Thus, the example electronic device 100 illustrated in FIG. 1 is for illustrative purposes only and is not intended to limit the scope of the invention. The mold compound 108 is formed such that the mold compound 108 encapsulates the substrate 104, the one or more dies 106, the internal leads 110, and the connection pads 114.

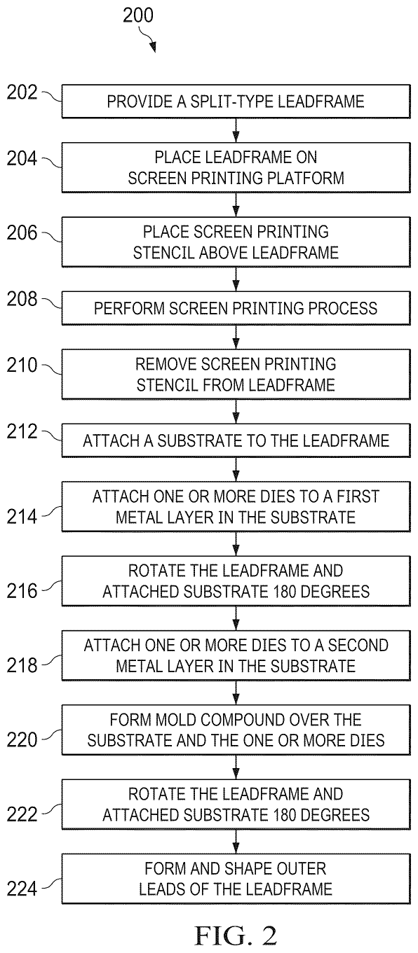

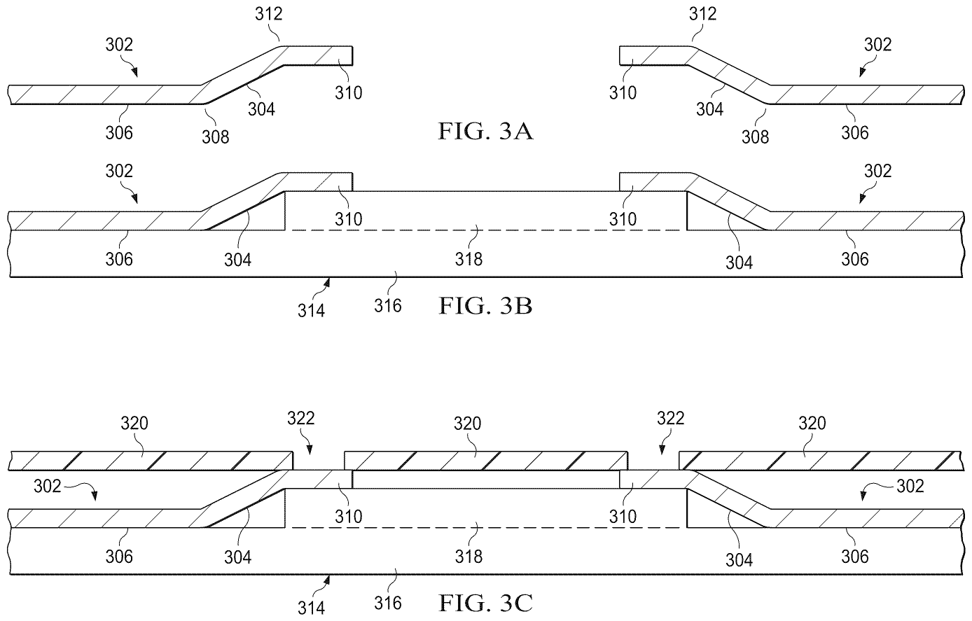

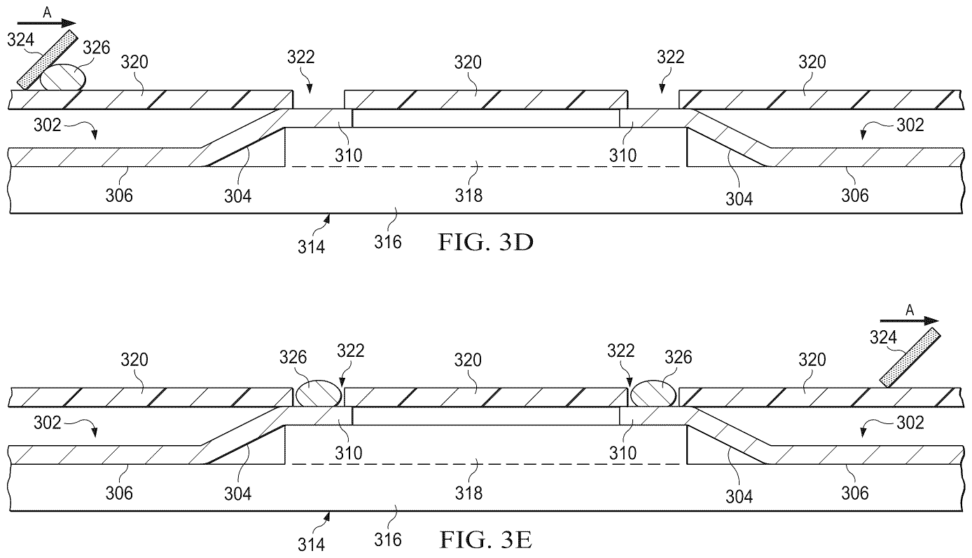

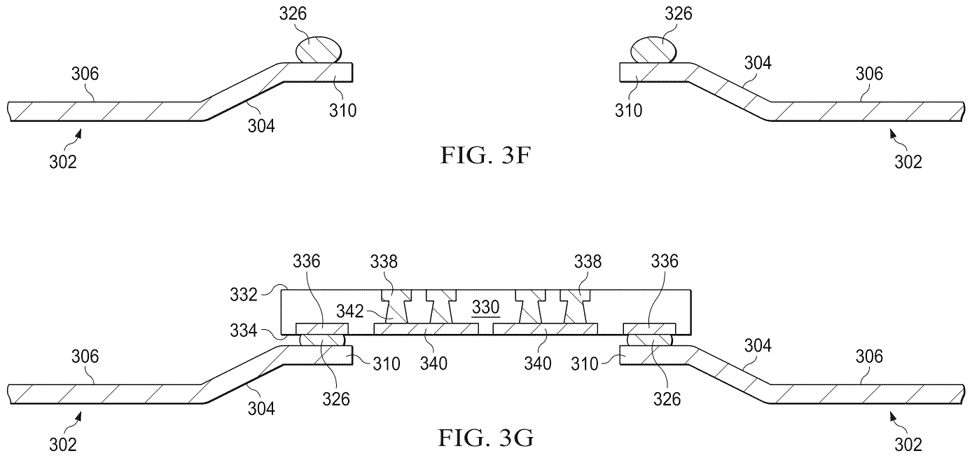

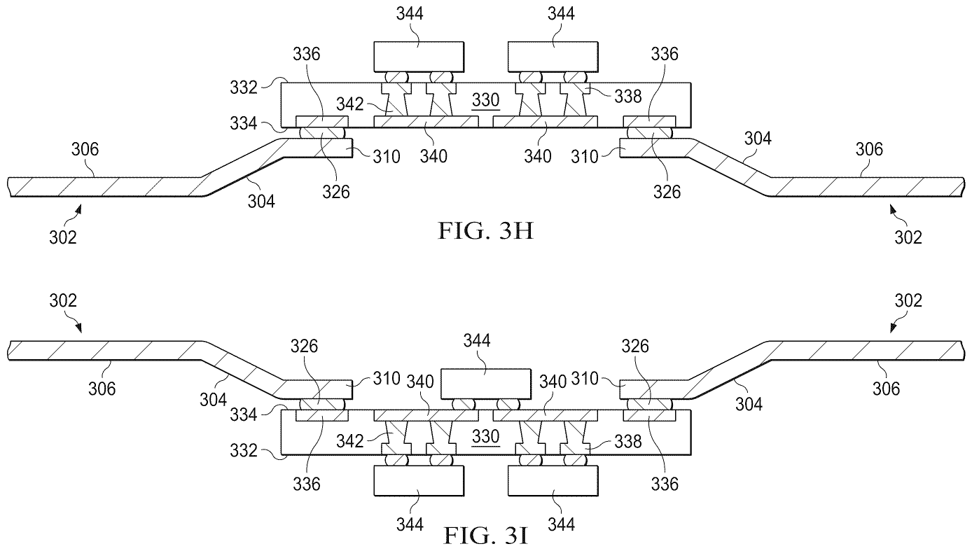

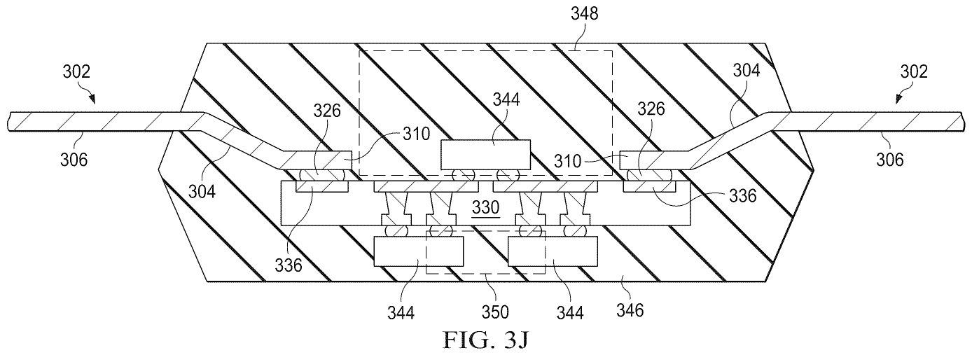

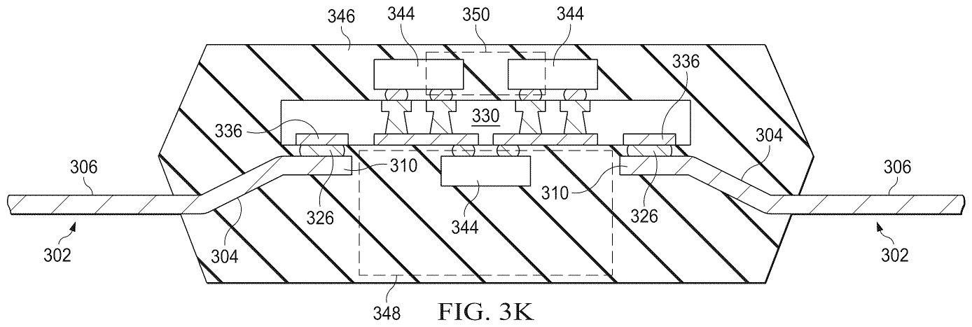

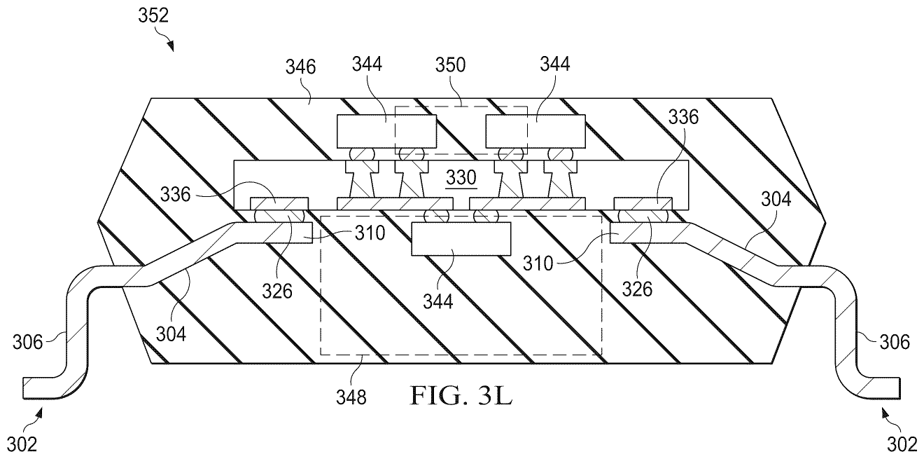

FIG. 2 is a block diagram flow chart explaining a fabrication process 200 and FIGS. 3A-3L illustrate the fabrication process associated with the formation of the electronic device 100 illustrated in FIG. 1. Though depicted sequentially as a matter of convenience, at least some of the actions shown can be performed in a different order and/or performed in parallel. Alternatively, some implementations may perform only some of the actions shown. Still further, although the example illustrated in FIGS. 2 and 3A-3L is an example method illustrating the example configuration of FIG. 1, other methods and configurations are possible. It is understood that although the method illustrated in FIGS. 2 and 3A-3L depicts the fabrication process of a single electronic device, the process applies to an array of electronic devices. Thus, after fabrication of the array of electronic devices the array is singulated to separate each electronic device 100 from the array.

Referring to FIG. 2 and to FIGS. 3A-3L, the fabrication process 200 of the electronic device 100 illustrated in FIG. 1 begins at 202 with a split-type leadframe 302. The leadframe 302 includes internal leads 304, external leads 306 extending from a first end 308 of the internal leads 304, and connection pads 310 extending from a second (opposite) end 312 of the internal leads 304. At 204, the leadframe 302 is placed on a screen printing platform 314 such that the external leads 306 are placed on a first (lower) platform 316 and the connection pads 310 are placed on a second (upper) platform 318 where the second platform 318 is elevated with respect to the first platform 316, resulting in the configuration of FIG. 3B.

At 206, a screen printing stencil 320 is placed on the leadframe 302 resulting in the configuration of FIG. 3C. The screen printing stencil 320 is substantially horizontal and is placed above the internal and external leads 304, 306 of the leadframe 302. The screen printing stencil, however, includes apertures 322 that are aligned with the connection pads 310. Thus, the screen printing stencil 320 is essentially attached on outer, opposite ends of the connection pads 310 thereby leaving the connection pads 310 exposed to receive an interconnect (e.g., solder) during the screen printing process. At 208, as illustrated in FIG. 3D, the leadframe 302 undergoes the screen printing process where a screen printing mechanism (e.g., brush, squeegee, etc.) 324 of a screen printing apparatus is passed across the screen printing stencil 320 and follows the horizontal configuration of the screen printing stencil 320 as indicated by the arrow A to deposit an interconnect (e.g., solder) 326 in the apertures 322 of the screen printing stencil 320 and onto the connection pads 310 resulting in the configuration of FIG. 3E.

At 210, the screen printing stencil 320 is removed from the leadframe 302 and the leadframe 302 is removed from the screen printing platform 314 resulting in the configuration of FIG. 3F. Since there are few connection points between the screen printing stencil 320 and the leadframe 302, there are no vibrations that occur in the leadframe 302 when the screen printing stencil 320 is removed from the leadframe 302. As a result, the deposited interconnect 326 does not become displaced from the connection pads 310.

At 212, a substrate 330 having a first surface 332 and a second surface 334 is attached to the leadframe 302, via a first thermal solder reflow process, resulting in the configuration of FIG. 3G. Specifically, the substrate 330 includes contact pads 336 embedded into the second surface 334 of the substrate 330. The contact pads 336 have an exposed surface that is substantially flush with the second surface 334 of the substrate 330. Thus, when attaching the substrate 330 to the leadframe 302, the exposed surface of the contact pads 336 attaches to the contact pads 310 via the deposited interconnect 326. The substrate 330 further includes a first metal layer 338, a second metal layer 340, and vias 342 connecting the first and second metal layers 338, 340. At 214, one or more dies 344 are connected to the first metal layer 338 via solder balls, via a second thermal solder reflow process, resulting in the configuration of FIG. 3H. At 216, the configuration of FIG. 3H is rotated 180° resulting in the configuration of FIG. 3I. At 218, one or more additional dies 344 are connected to the second metal layer 340 via solder balls, via a third thermal solder reflow process, resulting in the configuration of FIG. 3I.

At 220, a mold compound 346 is formed over and encapsulates the internal leads 304, the connection pads 310, the interconnects 326, the substrate 330, and the dies 344 resulting in the configuration of FIG. 3J. The configuration in FIG. 3J is reverse molded. In other words, the assembly of the leadframe 302, the substrate 330 and dies 344 is rotated upside down, as illustrated in FIG. 3I, during the molding process. The assembly is rotated upside down since during formation of the mold compound 346, the mold compound 346 flows more rapidly in larger spaces as opposed to smaller spaces. As a result, a small void can occur in the mold compound 346 in the smaller space. The small void, however, does not affect the performance of the electronic device. Specifically, the electronic device is configured to have a high-voltage area (e.g., 4 kv-5 kv) 348 in the larger space above the substrate 330, as illustrated in FIG. 3J (below the substrate 330 as illustrated in FIGS. 3K and 3L) and a low-voltage area (e.g., ground) 350 in the smaller space below the substrate 330, as illustrated in FIG. 3J (above the substrate 330 as illustrated in FIGS. 3K and 3L). As a result, a high electromagnetic field concentration will be present in the high-voltage area 348 and a low electromagnetic field concentration will be present in the low-voltage area 350. During formation of the mold compound 346, the mold compound 346 will fill the larger space where the high-voltage area 348 is present more rapidly than the smaller space where the low-voltage area 350 is present. This will in turn create a small void in the low-voltage are 350. Since this is a low-voltage area, however, the small void will not affect the performance of the electronic device, i.e., there will be no partial discharge. Conversely, if the void was present in the high-voltage area 348, the void would cause partial discharge resulting in electrical failures of the electronic device.

At 222, the configuration of FIG. 3J is rotated 180° resulting in the configuration of FIG. 3K. At 224, the external leads 306 of the leadframe 302 are formed and shaped to extend below the mold compound 346 so as to be mountable to an external electrical device (e.g., PCB) resulting in the electronic device 352 illustrated in FIG. 3L.

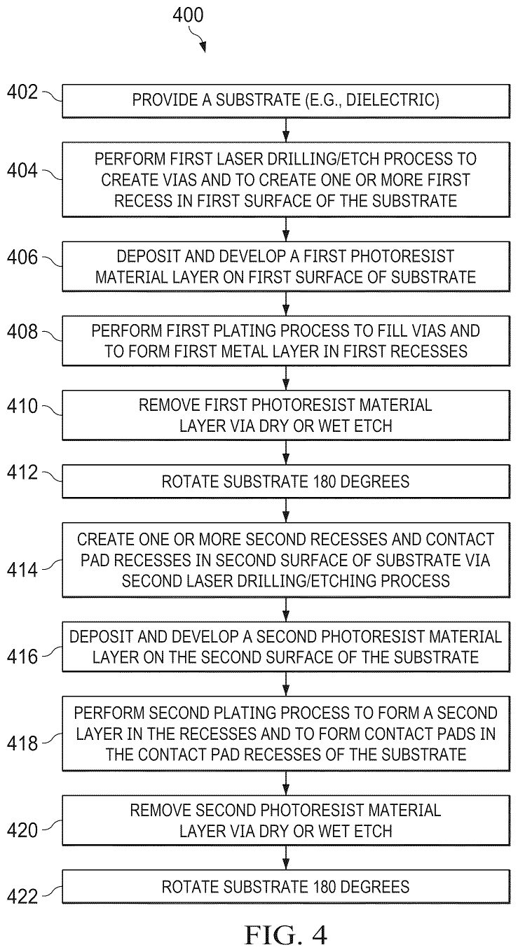

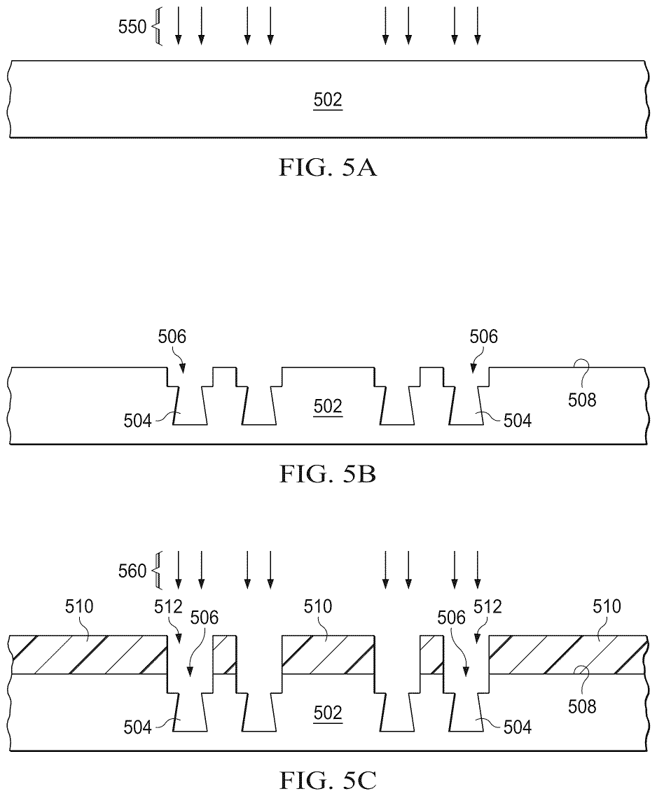

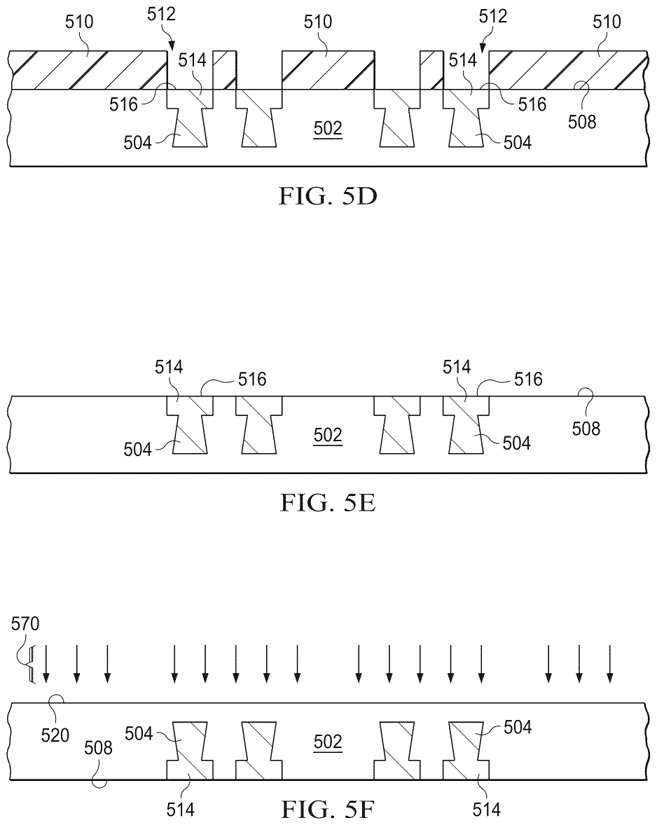

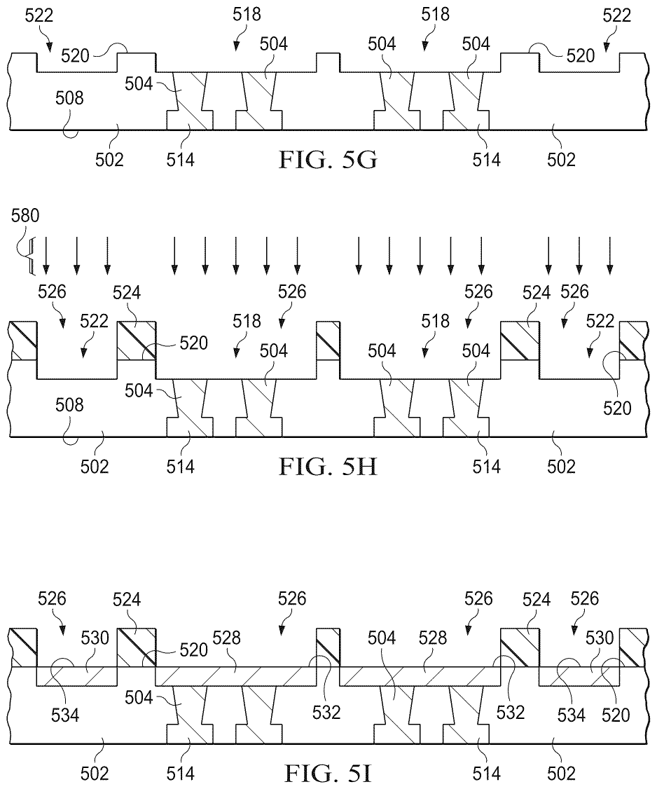

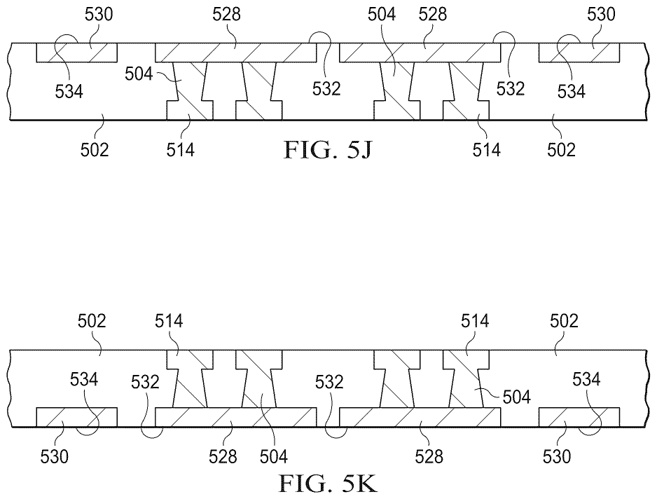

FIG. 4 is a block diagram flow chart explaining a fabrication process 400 and FIGS. 5A-5K illustrate the fabrication process associated with the formation of the substrate 104, 330 of the electronic device 100, 352 illustrated in FIGS. 1 and 3L respectively. Though depicted sequentially as a matter of convenience, at least some of the actions shown can be performed in a different order and/or performed in parallel. Alternatively, some implementations may perform only some of the actions shown. Still further, although the example illustrated in FIGS. 4 and 5A-5K is an example method illustrating the example configuration of the substrate 104, 330, other methods and configurations are possible. It is understood that although the method illustrated in FIGS. 4 and 5A-5K depicts the fabrication process of a substrate, the process applies to an array of substrates. Thus, after fabrication of the array of substrates the array is singulated to separate each substrate from the array.

Referring to FIG. 4 and to FIGS. 5A-5K, the fabrication process 400 begins at 402 with a substrate 502. At 404, the configuration in FIG. 5A undergoes a first laser drilling/etching process 550 to drill vias 504 and to etch one or more first recesses 506 in a first surface 508 of the substrate 502 resulting in the configuration of FIG. 5B. At 406, a first photoresist material layer 510 overlies the first surface 508 of the substrate 502 and is patterned and developed to expose openings 512 in the first photoresist material layer 510 over the substrate 502, resulting in the configuration of FIG. 5C. The first photoresist material layer 510 can have a thickness that varies in correspondence with the wavelength of radiation used to pattern the first photoresist material layer 510. The first photoresist material layer 510 may be formed over the substrate 502 via spin-coating or spin casting deposition techniques, selectively irradiated (e.g., via deep ultraviolet (DUV) irradiation) and developed to form the openings 512.

At 408, the configuration in FIG. 5C undergoes a first plating (electroplating) process 560 resulting in the configuration of FIG. 5D. Specifically, the vias 504 are filled with a conductive material (e.g., copper) and a first metal layer (trace) (e.g., copper) 514 is plated in the one or more recess 506 of the substrate 502. The first metal layer 514 is plated such that an exposed (top) surface 516 of the first metal layer 514 is substantially flush with the first surface 508 of the substrate 502. The configuration of the first metal layer 514 can be comprised a single solid metal portion or can be comprised of multiple metal portions physically separated by a gap or gaps, as illustrated in FIG. 5D. Thus, the number of recesses 506 etched in the first surface 508 of the substrate 502 can be a single recess or more than one recess separated by a gap or gaps to accommodate more than one metal portions that comprise the first metal layer 514. Therefore, the example first metal layer 514 illustrated in FIG. 5D is for illustrative purposes only and is not intended to limit the scope of the invention.

At 410, the first photoresist material layer 510 is removed via a dry or wet etch process resulting in the configuration of FIG. 5E. At 412, the configuration in FIG. 5E is rotated 180° resulting in the configuration of FIG. 5F. At 414, the configuration of FIG. 5F undergoes a second laser drilling/etching process 570 to etch one or more second recesses 518 in a second surface 520 of the substrate 502 opposite that of the first surface 508 resulting in the configuration of FIG. 5G. The substrate 502 is additionally modified by the second laser drilling/etching process 570 to etch contact pad recesses 522 near a perimeter of the substrate 502.

At 416, a second photoresist material layer 524 overlies the second surface 520 of the substrate 502 and is patterned and developed to expose openings 526 in the second photoresist material layer 524 over the substrate 502, resulting in the configuration of FIG. 5H. The second photoresist material layer 524 can have a thickness that varies in correspondence with the wavelength of radiation used to pattern the second photoresist material layer 524. The second photoresist material layer 524 may be formed over the substrate 502 via spin-coating or spin casting deposition techniques, selectively irradiated (e.g., via deep ultraviolet (DUV) irradiation) and developed to form the openings 526.

At 418, the configuration in FIG. 5H undergoes a second plating (electroplating) process 580 to plate a second metal layer (trace) (e.g., copper) 528 in the second recesses 518 and to plate contact pads 530 in the contact pad recesses 522 of the substrate 502 resulting in the configuration of FIG. 5I. The second metal layer 528 is plated such that an exposed (bottom) surface 532 of the second metal layer 528 is substantially flush with the second surface 520 of the substrate 502. In addition, the contact pads 530 are plated such that an exposed (bottom) surface 534 of the contact pads 530 is substantially flush with the second surface 520 of the substrate 502. The configuration of the second metal layer 528 can be comprised of a single solid metal portion or can be comprised of multiple metal portions physically separated by a gap or gaps. For simplicity, the configuration of the second metal layer 528 is a pair of metal portions. Thus, the number of recesses etched in the second surface 520 of the substrate 502 can be a single recess or more than one recess separated by a gap or gaps to accommodate more than one metal portions that comprise the second metal layer 528. Therefore, the example second metal layer 528 illustrated in FIG. 5I is for illustrative purposes only and is not intended to limit the scope of the invention. At 420, the second photoresist material layer 524 is removed via a dry or wet etch process resulting in the configuration of FIG. 5J. At 422, the configuration in FIG. 5J is again rotated 180° resulting in the configuration of FIG. 5K.

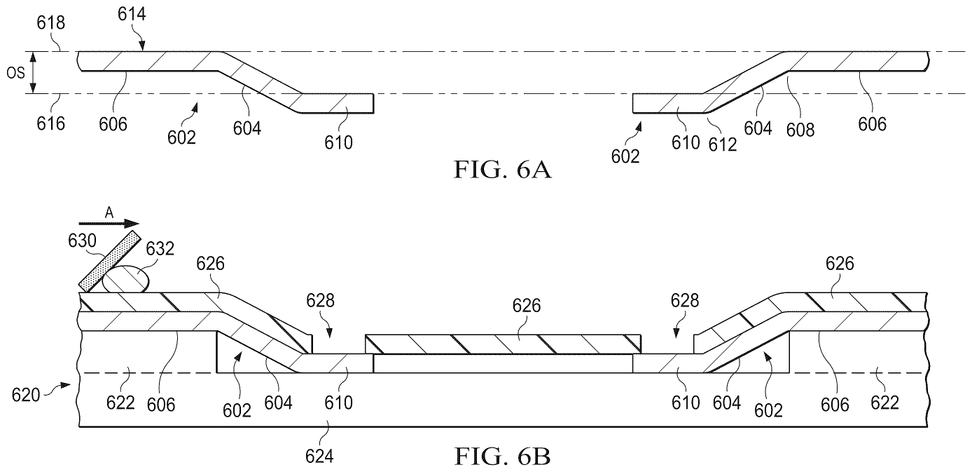

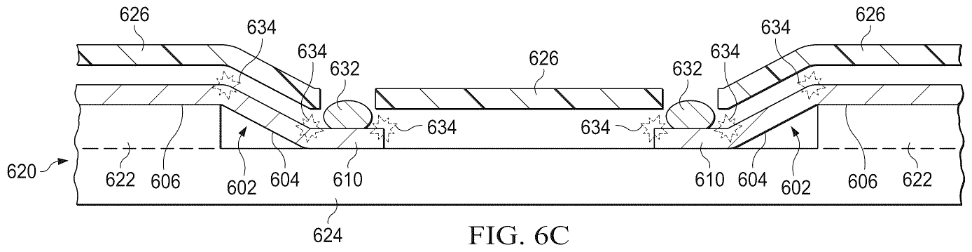

FIG. 6A is a cross-sectional view of another example leadframe 602 and FIGS. 6B and 6C are cross-sectional views of another example screen printing apparatus. The leadframe is a split-type leadframe and includes internal leads 604, external leads 606 extending from a first end 608 of the internal leads 604, and pads 610 extending from a second end 612 of the internal leads 604. As illustrated in FIG. 6A, the pads 610 are off-set in a direction below the leadframe 602 represented by OS. Specifically, the pads 610 are offset below a top portion 614 of the external leads 606. In other words, the pads 610 are on a first plane 616 and the top portion 614 of the external leads 606 are on a second plane 618 are on a second plane 618, where the first plane 616 is positioned below the second plane 618.

Referring to FIGS. 6B and 6C, the screen printing apparatus includes a platform 620 including an upper platform 622 and a lower platform 624. During a solder screen printing process, the leadframe 602 is placed on a screen printing platform 620 such that the external leads 606 are placed on the upper platform 622 and the pads 610 are placed on the lower platform 624 where the lower platform 624 is positioned below the upper platform 622. The screen printing apparatus further includes a stencil 626 that is placed on the leadframe 602. The stencil 626 includes openings 628 that are aligned with the pads 610.

During the screen printing process a screen printing mechanism (e.g., brush, squeegee, etc.) 630 is passed across the stencil 626 as indicated by the arrow A to deposit solder 632 in the openings 628 of the stencil 626 and onto the pads 610 as illustrated in FIG. 6C. Upon removal of the stencil 626 from the leadframe 602 vibrations 634 occur connection points between the stencil 626 and the leadframe 602. As a result of the vibrations 634, the deposited solder 632 becomes displaced from the pads 610. In some instances, the solder 632 may become so displaced that the solder 632 falls over an edge of the pads 610 and is thus completely displaced from the pads 610 thereby preventing a substrate, as described herein, from being properly attached to the leadframe 602. These problems in turn cause performance and quality issues of the electronic device.

Described above are examples of the subject disclosure. It is, of course, not possible to describe every conceivable combination of components or methodologies for purposes of describing the subject disclosure, but one of ordinary skill in the art may recognize that many further combinations and permutations of the subject disclosure are possible. Accordingly, the subject disclosure is intended to embrace all such alterations, modifications and variations that fall within the spirit and scope of the appended claims. In addition, where the disclosure or claims recite “a,” “an,” “a first,” or “another” element, or the equivalent thereof, it should be interpreted to include one or more than one such element, neither requiring nor excluding two or more such elements. Furthermore, to the extent that the term “includes” is used in either the detailed description or the claims, such term is intended to be inclusive in a manner similar to the term “comprising” as “comprising” is interpreted when employed as a transitional word in a claim. Finally, the term “based on” is interpreted to mean based at least in part.

What is claimed is:

1. An electronic device comprising:
a leadframe having connection pads, the connection pads being off-set in a direction elevated from the leadframe;
a substrate attached to the leadframe;
at least one die attached to the substrate; and
a mold compound encapsulating the substrate and the at least one die.

2. The electronic device of claim 1, wherein the leadframe further includes internal leads and external leads, the external leads extending from a first end of the internal leads, and wherein the connection pads extend from a second end of the internal leads.

3. The electronic device of claim 2, wherein the connection pads are on a first plane and a top of the external leads are on a second plane, and wherein the first plane is elevated with respect to the second plane.

4. The electronic device of claim 1, wherein the substrate includes a first metal layer embedded in a first surface of the substrate, a second metal layer embedded in a second surface of the substrate, and vias electrically connecting the first metal layer and the second metal layer.

5. The electronic device of claim 4, wherein the substrate further includes contact pads embedded in the second metal layer, the contacts pads having an exposed surface that is substantially flush with the second surface of the substrate, the exposed surface of the contact pads attaching to the connection pads of the leadframe via interconnects.

6. The electronic device of claim 5, wherein the first metal layer includes an exposed surface that is substantially flush with the first surface of the substrate and the second metal layer includes an exposed surface that is substantially flush with the second surface of the substrate.

7. The electronic device of claim 6, wherein the at least one die includes at least one first die attached to the exposed surface of the first metal layer and at least one second die attached to the exposed surface of the second metal layer.

8. A method comprising:
placing a leadframe on a platform such that external leads of the leadframe are placed on a first platform and connection pads of the leadframe are placed on a second platform, the second platform being elevated with respect to the first platform;
placing a stencil above the leadframe such that the stencil is placed on outer, opposite ends of the connection pads, the stencil including apertures aligned with the connection pads;
performing a screen printing process to deposit an interconnect in the apertures of the stencil and on the connection pads;
attaching a substrate to the connection pads of the leadframe via the interconnect;
attaching at least one die to the substrate; and
forming a mold compound to encapsulate the substrate and the at least one die.

9. The method of claim 8, wherein performing a screen printing process to deposit an interconnect in the apertures and on the connection pads includes passing a screen printing mechanism across the stencil in a substantially horizontal direction to deposit the interconnect on the connection pads.

10. The method of claim 8, wherein prior to attaching a substrate to the connection pads of the leadframe, the method includes removing the stencil from the leadframe and removing the leadframe from the platform.

11. The method of claim 8, wherein attaching at least one die to the substrate includes attaching at least one first die to a first metal layer in a first surface of the substrate and attaching at least one second die to a second metal layer in a second surface of the substrate.

12. The method of claim 11, wherein attaching a substrate to the connection pads of the leadframe via an interconnect includes attaching an exposed surface of contact pads in the second surface of the substrate to the connection pads of the leadframe via the interconnect.

13. An electronic device comprising:
a leadframe having internal leads, external leads, and connection pads, the connection pads being off-set in a direction elevated from a top portion of the external leads;
a substrate attached to the leadframe;
at least one die attached to the substrate; and
a mold compound encapsulating the substrate and the at least one die.

14. The electronic device of claim 13, wherein the external leads extend from a first end of the internal leads, and the connection pads extend from a second end of the internal leads.

15. The electronic device of claim 13, wherein the connection pads are on a first plane and the top of the external leads are on a second plane, and wherein the first plane is elevated with respect to the second plane.

16. The electronic device of claim 13, wherein the substrate includes a first metal layer embedded in a first surface of the substrate, a second metal layer embedded in a second surface of the substrate, and vias electrically connecting the first metal layer and the second metal layer.

17. The electronic device of claim 16, wherein the substrate further includes contact pads embedded in the second metal layer, the contacts pads having an exposed surface that is substantially flush with the second surface of the substrate, the exposed surface of the contact pads attaching to the connection pads of the leadframe via interconnects.

18. The electronic device of claim 17, wherein the first metal layer includes an exposed surface that is substantially flush with the first surface of the substrate and the second metal layer includes an exposed surface that is substantially flush with the second surface of the substrate.

19. The electronic device of claim 18, wherein the at least one die is comprised of a first die and a second die, the first die and the second die being attached to the exposed surface of the first metal layer.

20. The electronic device of claim 19 further comprising a third die attached to the exposed surface of the second metal layer.
